(19) United States
(12) Patent Application Publication
(10) Pub. No.: US 2019/0229064 A1
(43) Pub. Date: Jul. 25, 2019

(54) LASER COLOR MARKING METHOD FOR A SEMICONDUCTOR PACKAGE

(71) Applicant: Powertech Technology Inc., Hukou Township (TW)

(72) Inventors: Chin-Ta Wu, Hukou Township (TW); Sheng-Tou Tseng, Hukou Township (TW); Kuo-Jhan Kao, Hukou Township (TW); Ying-Lin Chen, Hukou Township (TW); Cheng-Hung Song, Hukou Township (TW); Hung-Chieh Huang, Hukou Township (TW); Kun-Chi Hsu, Hukou Township (TW)

(73) Assignee: Powertech Technology Inc., Hukou Township, OR (US)

(21) Appl. No.: 15/879,305

(22) Filed: Jan. 24, 2018

(51) Int. Cl. H01L 23/544; H01L 21/3205; H01L 21/268; H01L 23/31; H01L 21/285; H01L 21/321; H01L 23/552

(52) U.S. Cl. CPC H01L 23/544; H01L 21/32051; H01L 21/268; H01L 2223/54433; H01L 21/2855; H01L 21/321; H01L 23/552; H01L 23/3128

(57) ABSTRACT

A laser color marking method for a semiconductor package has steps of: (a) providing a semiconductor element; (b) sputtering a metal layer on the semiconductor element; (c) obtaining a marking pattern; and (d) applying a laser light source on the marking region to form a mark according to the marking pattern. The mark is consisted of an optical oxide film converting ambient light to a corresponding color light, so a visible color mark is marked. Therefore, the present invention easily laser-marks the visible color mark on the semiconductor package.

### BACKGROUND OF THE INVENTION

### 1. Field of the Invention

The present invention is related to a laser marking method for semiconductor package, and more particularly to a laser color marking method for a semiconductor package.

### 2. Description of the Prior Arts

In a semiconductor package with a high-speed chip or chip set, an outer metal element is usually required to be used as a heat sink. With reference to FIGS. 5A to 5C, the outer metal element 60 is previously fabricated and then mounted onto the semiconductor element 50 to form a semiconductor package 50′.

In general, with reference to FIG. 5A, the outer metal element 60 is made of a metal plate 601 made of a single material such as Cu, Al etc. Since the outer metal element 60 is mounted onto the semiconductor element 50, a product mark 61 is marked on the outer metal element 60 by a laser L in the marking step of the packaging process as shown in FIG. 6A. The product mark 61 usually includes a product logo, a product trademark or a product number etc.

Currently, the outer metal element 60 only has a black and white mark 61 thereon; so a color mark is not marked by the laser L. In addition, the shape of the mark 61 is vague when the mark 61 is marked on a rough surface of the metal element 60. To increase identification of the mark, as shown in FIG. 6B, the depth d of the mark 61 marked on the outer metal element 60 is further increased. However, if the laser is not controlled well to form a deeper depth d of the mark 61, an internal structure of the semiconductor element 50 would be damaged by the laser L. The abnormal condition of the semiconductor package 50′ is then occurred.

A color mark may be printed on the outer metal element of the semiconductor package by a color ink printing technique, but the ink printing cost would be higher than a laser marking cost.

To overcome the shortcomings of the laser marking technique, the present invention provides a laser color marking method for a semiconductor package to mitigate or obviate the aforementioned problems.

### SUMMARY OF THE INVENTION

An objective of the present invention is to provide a laser color marking method for a semiconductor package.

To achieve the objective as mentioned above, the laser color marking method has steps of:

(a) providing a semiconductor element;

(b) sputtering a metal layer on the semiconductor element, wherein the metal layer has a marking region;

(c) obtaining a marking pattern; and

(d) applying a laser light on the marking region to form a mark according to the marking pattern, wherein the mark has an optical oxide film with a first thickness and the optical oxide film converts ambient light to a first color light to present a visible color mark.

Based on the foregoing description, in the laser color marking method, the metal layer is directly formed on the semiconductor element by a sputtering process. The laser light is directly provided on the metal layer to form an optical oxide film to convert the ambient light to the corresponding color light, so a visible color mark is marked. Therefore, the present invention does not require an external metal element and no other mounting metal element step is added in the packaging process.

To achieve the objective as mentioned above, another laser color marking method has steps of:

(a) providing a semiconductor element that has an outer alloy metal layer, wherein the outer alloy metal layer has a marking region;

(b) obtaining a marking pattern; and

(c) applying a laser light on the marking region to form a mark according to the marking pattern, wherein the mark has an optical oxide film with a first thickness and the optical oxide film converts ambient light to a first color light to present a visible color mark.

Based on the foregoing description, the laser color marking method uses the alloy metal layer formed on the semiconductor element. The optical oxide film is formed on a surface of the alloy metal layer after the laser light is provided thereon. The optical oxide film converts the ambient light to the corresponding color light, so a visible color mark is marked. Therefore, the present invention can easily form the visible color mark on the alloy metal layer by the laser light.

Other objectives, advantages and novel features of the invention will become more apparent from the following detailed description when taken in conjunction with the accompanying drawings.

### BRIEF DESCRIPTION OF THE DRAWINGS

FIG. 1A is a cross sectional view of a semiconductor element in accordance with the present invention;

FIG. 1B is an operational view of sputtering a metal layer on a semiconductor element in accordance with the present invention;

FIGS. 2A is an operational view of a laser color marking step in accordance with the present invention;

FIG. 2B is a top plan view of a semiconductor package in accordance with the present invention;

FIG. 3A is an enlarged cross sectional view of a part of the semiconductor package in accordance with the present invention;

FIG. 3B is a light-refracting schematic view of one different optical oxide film in accordance with the present invention;

FIG. 3C is an enlarged cross sectional view of a part of another semiconductor package in accordance with the present invention;

FIG. 3D is a light-refracting schematic view of two different optical oxide films in accordance with the present invention;

FIG. 4A is a flow chart of a first embodiment of a laser color marking method in accordance with the present invention;

FIG. 4B is a flow chart of a second embodiment of a laser color marking method in accordance with the present invention;

FIG. 5A is an operational view of fabricating a metal element of a semiconductor package in accordance with the prior art;

FIGS. 5B and 5C are operational views of mounting the metal element on a semiconductor element in accordance with the prior art;

FIG. 6A is an operational view of a laser marking step in accordance with the prior art; and

FIG. 6B is an enlarged cross sectional view of a part of the semiconductor package in accordance with the prior art.

### DETAILED DESCRIPTION OF THE PREFERRED EMBODIMENTS

The present invention provides a laser color marking method to form a color mark on the semiconductor package. With embodiments and drawings thereof, the features of the present invention are described in detail as follow.

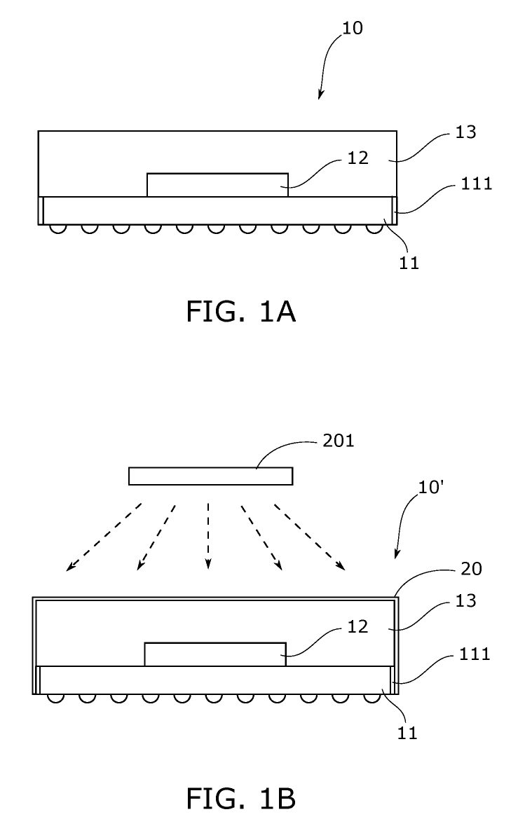

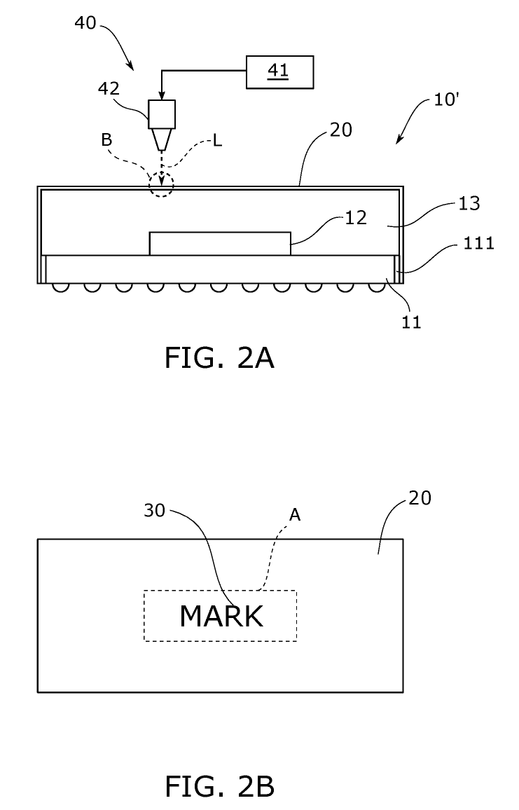

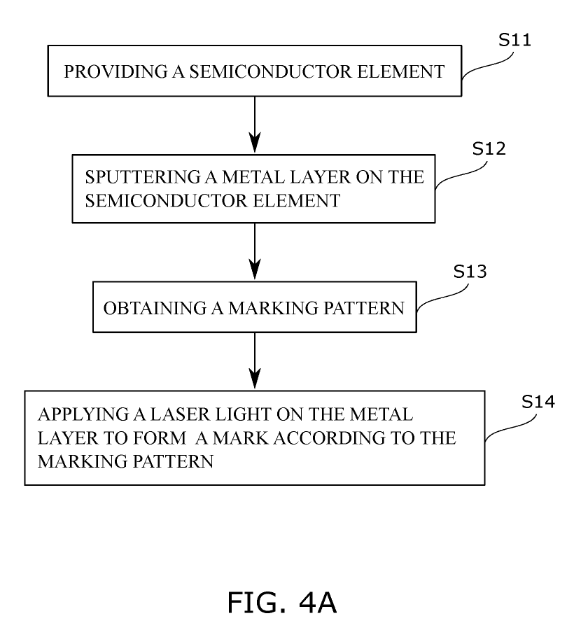

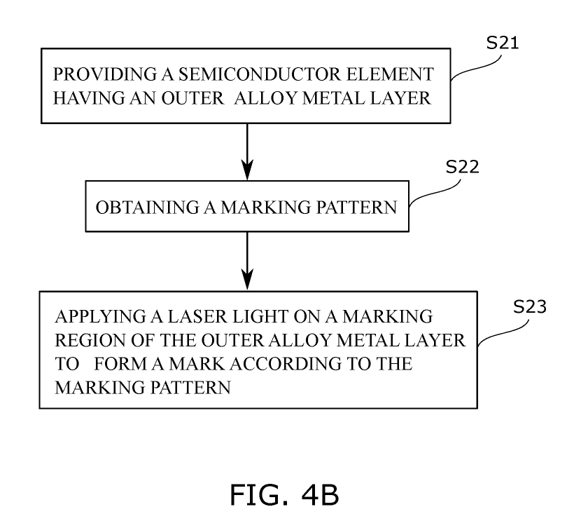

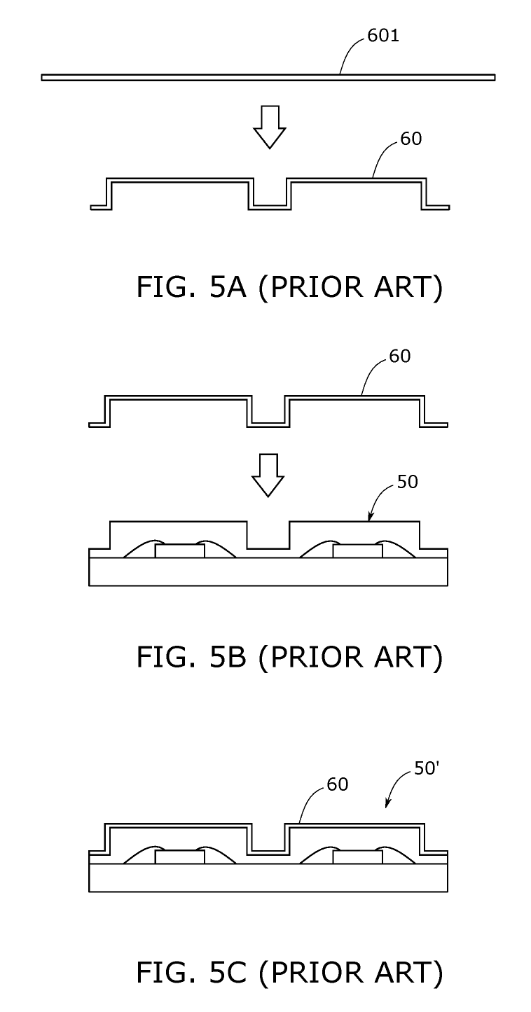

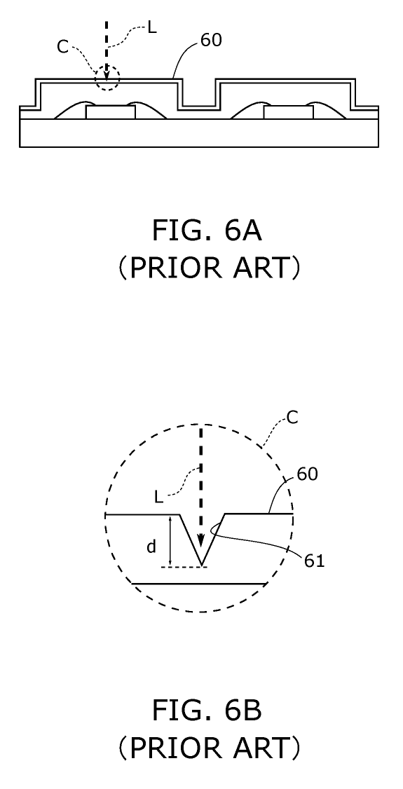

With reference to FIGS. 1A and 4A, the first embodiment of the laser color mark method is shown and has steps of: (a) providing a semiconductor element 10 (S11); (b) forming a metal layer 20 on the semiconductor element 10 (S12), as shown in FIG. 1B; (c) obtaining a marking pattern (S13); and (d) applying a laser light L on the metal layer 20 to form a mark 30 according to the marking pattern (S14), as shown in FIGS. 2A and 2B.

With reference to FIG. 1A, in the step (a) S11, the semiconductor element 10 has a substrate 11 with at least one chip 12 mounted onto the substrate 10 and an encapsulation 13 encapsulating the chip 12 and on top of the substrate 11. The substrate 11 has a ground pad 111 electronically connected to the ground of an IC system power.

With further reference to FIG. 1B, an alloy material 201 is formed on the semiconductor element 10. The alloy material 201 may be formed on the semiconductor element 10 through sputtering in a sputtering chamber (not shown). In the sputtering chamber, the metal layer 20 is securely formed on the encapsulation 13 of the semiconductor element 10 and the ground pad 111 of the substrate 11. Therefore, in the step (b) S12, the metal layer 20 is formed on the semiconductor element 10 by a sputtering process to form a semiconductor package 10′. When the metal layer 20 is electrically coupled to the ground pad, the metal layer 20 may be used as an EMI shelter to protect the semiconductor package 10′ from the EMI radiation from the surrounding radiation sources. With reference to FIG. 2B, the metal layer 20 has a marking region A. The alloy material 201 is made of Fe, Cr, Ni and Mn, so steel (SUS) may be used as alloy material 201.

With further reference to FIG. 2A, a laser marking device 40 is used and has a controller 41 and a laser light source 42 controlled by the controller 41. The laser marking device 40 may be used to generate a picosecond laser light or nanosecond laser light. In the step (c) S13, the controller 41 obtains the marking pattern. In the step (d) S14, the controller 41 controls the laser light source 42 to generate the laser light L on the marking region A according to the marking pattern. In addition, the controller 41 further controls an energy of the laser light L provided to the marking region A.

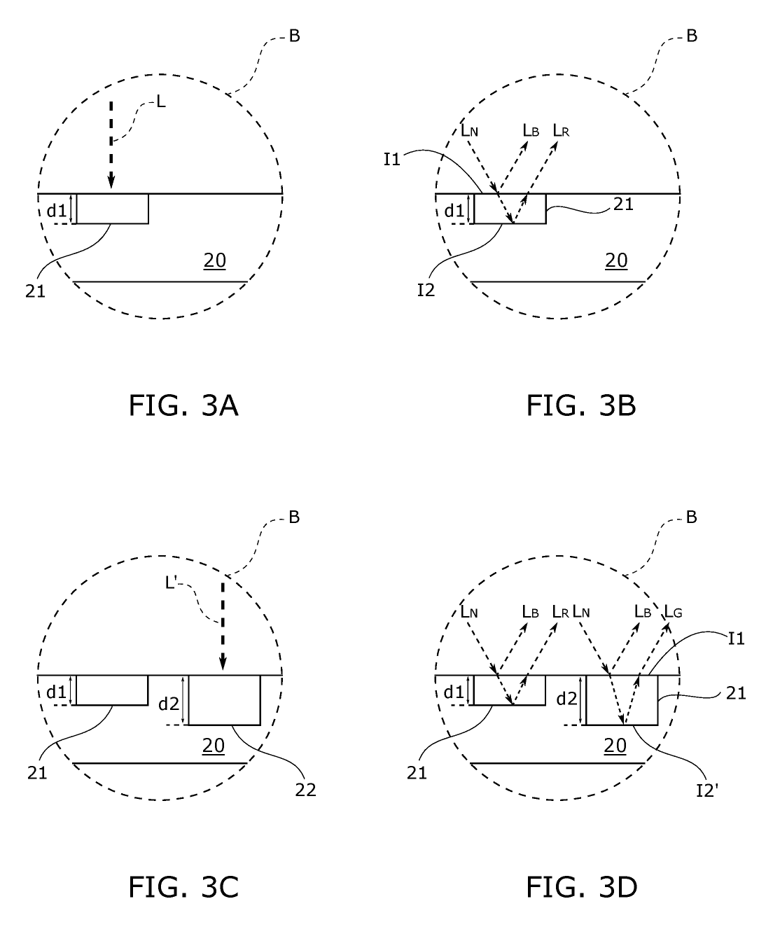

With further reference to FIG. 3A, an optical oxide layer 21 is formed on the metal layer 20 after the laser light L provided to the marking region A. Since the energy of the laser light L is controlled, a thickness d1 or d2 of the optical thin film 21 or 22 is controllable as well, as shown in FIG. 3C.

With reference to FIG. 3B, the optical oxide film 21 has a first thickness d1. A first interface I1 between the air and a top of the optical oxide film 21 reflects and converts a part of ambient light L_{N} to a first color light L_{B} such as blue light. The rest of the ambient light L_{N} is refracted into the optical oxide film 21 and then reflected at a second interface 12 between a bottom of the optical oxide film 21 and the metal layer 20 to convert a second color light L_{R}, such as red light. Therefore, the blue and red lights L_{B}, L_{R} are mixed to generate a visible magenta light. The mark 30 consisted of the optical oxide film 21 is a visible and colored mark, as shown in FIG. 2B.

With reference to FIG. 3C, to form a visible multi-color mark, another optical oxide film 22 has a second thickness d2 is formed by the laser light L′ with the larger energy. The second thicknesses d2 differs from the first thickness dl. For example, the thickness d2 may be greater than the thickness d1. With further reference to FIGS. 2B and 3D, the mark 30 on the marking region A is consisted of the optical oxide films 21, 22 with different thicknesses d1, d2. A part of the ambient light L_{N} refracted into the optical oxide film 22 is reflected at a second interface 12′ between a bottom of the optical oxide film 22 and the metal layer 20 to convert a third color light L_{G}, such as green light. Therefore, the blue and red lights L_{B}, L_{G} are mixed to generate a visible light-blue light and the visible multi-color mark 30 consisted of the optical oxide films 21, 22 with different thicknesses dl, d2 is provided.

In the first embodiment of the laser color marking method, when SUS 304 is used as the alloy material, the metal layer 20 is made of SUS 304. When the laser light supplies to the metal layer 20 that is made of SUS 304, the optical oxide layer thereof converts a corresponding color light. Here are the different color lights converted by the optical oxide film with different compositions.
1. The optical oxide film converts a red light when the optical oxide film consists of (NiCr₂O₄), Fe+2Cr₂O₄, Fe₃O₄, Fe₂O₃, NiFe₂O₄ and Fe₂93O₄.
2. The optical oxide film converts a blue light when the optical oxide film consists of Cr₃C₂, Cr₃N_{0.4}C_{1.6}, Cr₃C(C_{0.52}NO_{0.48}), C and Cr₇C₃.
3. The optical oxide film converts a white light when the optical oxide film consists of C, Cr₃C₂, C₁52Cr₃N_{0.48} and Cr₃N_{0.4}C_{1.6}.
4. The optical oxide film converts a gold light when the optical oxide film consists of Cr₃N_{0.4}C_{1.6}, C, Cr₃C₂, NiCr₂O₄ and C₁52Cr₃N_{0.48}.

With reference to FIGS. 1 and 4B, the second embodiment of the laser color marking method of the present invention is shown and has steps of: (a) providing a semiconductor element 10 that has an outer alloy metal layer 20 and a surface of the outer alloy metal layer 20 has a marking region A (S21); (b) obtaining a marking pattern (S22); and (c) applying a laser light L on the marking region A to form mark 30 (S23), as shown in FIGS. 2A and 2B.

The outer alloy metal layer 20 may be made of an alloy material, such as SUS 304. When the laser light supplies to the metal layer 20 that is made of SUS 304, the optical oxide layer thereof converts a corresponding color light, as mentioned above.

Based on the foregoing description, in the laser color marking method, the metal layer is directly formed on the semiconductor element by a sputtering process. The laser light is directly provided on a surface of the metal layer to form an optical oxide film to convert the ambient light to the corresponding color light. Therefore, the present invention uses the laser light to mark the visible color mark and does not require an external metal element or other mounting metal element step in the packaging process.

Even though numerous characteristics and advantages of the present invention have been set forth in the foregoing description, together with the details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A laser color marking method for a semiconductor package, comprising steps of:
(a) providing a semiconductor element;
(b) sputtering a metal layer on the semiconductor element, wherein the metal layer has a marking region;
(c) obtaining a marking pattern; and
(d) applying a laser light on the marking region to form a mark according to the marking pattern, wherein the mark has an optical oxide film with a first thickness and the optical oxide film converts an ambient light to a first color light to present a visible color mark.

2. The laser color marking method as claimed in claim 1, the step (d) further comprising: adjusting an energy of the laser light accumulated on the marking region to partially form the optical oxide film with a second thickness to convert the ambient light to a second color light to present a visible multi-color mark.

3. The laser color marking method as claimed in claim 1, wherein:
the semiconductor element has a substrate, at least one chip mounted on the substrate and an encapsulation encapsulating the at least one chip and a part of the substrate; and
the metal layer is sputtered on the encapsulation.

4. The laser color marking method as claimed in claim 2, wherein:
the semiconductor element has a substrate, at least one chip mounted on the substrate and an encapsulation encapsulating the at least one chip and a part of the substrate; and
the metal layer is sputtered on the encapsulation.

5. The laser color marking method as claimed in claim 3, wherein the substrate has a ground pad connected to the metal layer.

6. The laser color marking method as claimed in claim 4, wherein the substrate has a ground pad connected to the metal layer.

7. The laser color marking method as claimed in claim 1, wherein the metal layer is made of an alloy at least comprising Fe, Cr, Ni and Mn.

8. The laser color marking method as claimed in claim 2, wherein the metal layer is made of an alloy at least comprising Fe, Cr, Ni and Mn.

9. The laser color marking method as claimed in claim 7, wherein:
the metal layer is made of SUS 304; and
the optical oxide film optionally converts:
a red light when the optical oxide film consisting of (NiCr₂O₄), Fe+2Cr₂O₄, Fe₃O₄, Fe₂O₃, NiFe₂O₄ and Fe₂93O₄;
a blue light when the optical oxide film consisting of Cr₃C₂, Cr₃N_{0.4}C_{1.6}, Cr₃C(C_{0.52}N_{0.48}), C and Cr₇C₃;
a white light when the optical oxide film consisting of C, Cr₃C₂, C₁52Cr₃N_{0.48} and Cr₃N_{0.4}C_{1.6}; and
a gold light when the optical oxide film consisting of Cr₃N_{0.4}C_{1.6}, C, Cr₃C₂, NiCr₂O₄ and C₁52Cr₃N_{0.48}.

10. The laser color marking method as claimed in claim 1, the laser light is a picosecond laser light or a nanosecond laser light.

11. A laser color marking method for semiconductor package, comprising steps of:
(a) providing a semiconductor element having an outer alloy metal layer, wherein the outer alloy metal layer has a marking region;
(b) obtaining a marking pattern; and
(c) applying a laser light on the marking region to form a mark according to the marking pattern, wherein the mark has an optical oxide film with a first thickness and the optical oxide film converts ambient light to a first color light to present a visible color mark.

12. The laser color marking method as claimed in claim 11, the step (c) further comprising: adjusting an energy of the laser light accumulated on the marking region to partially form the optical oxide film with a second thickness to convert the ambient light to a second color light to present a visible multi-color mark.

13. The laser color marking method as claimed in claim 11, wherein:
the semiconductor element has a substrate, at least one chip is mounted onto the substrate and an encapsulation encapsulating the at least one chip and a part of the substrate; and
the outer alloy metal layer is sputtered on the encapsulation.

14. The laser color marking method as claimed in claim 12, wherein:
the semiconductor element has a substrate, at least one chip is mounted onto the substrate and an encapsulation encapsulating the at least one chip and a part of the substrate; and
the outer alloy metal layer is sputtered on the encapsulation.

15. The laser color marking method as claimed in claim 13, wherein the substrate has a ground pad connected to the outer alloy metal layer.

16. The laser color marking method as claimed in claim 14, wherein the substrate has a ground pad connected to the outer alloy metal layer.

17. The laser color marking method as claimed in claim 11, wherein the outer alloy metal layer is made of Fe, Cr, Ni and Mn.

18. The laser color marking method as claimed in claim 12, wherein the outer alloy metal layer is made of Fe, Cr, Ni and Mn.

19. The laser color marking method as claimed in claim 17, wherein:
the outer alloy metal layer is made of SUS 304; and
the optical oxide film optionally converts:
a red light when the optical oxide film consisting of (NiCr₂O₄), Fe+2Cr₂O₄, Fe₃O₄, Fe₂O₃, NiFe₂O₄ and Fe₂93O₄;
a blue light when the optical oxide film consisting of Cr₃C₂, Cr₃N_{0.4}C_{1.6}, Cr₃C(C_{0.52}N_{0.48}), C and Cr₇C₃;
a white light when the optical oxide film consisting of C, Cr₃C₂, C₁52Cr₃N_{0.48} and Cr₃N_{0.4}C_{1.6}; and
a gold light when the optical oxide film consisting of Cr₃N_{0.4}C_{1.6}, C, Cr₃C₂, NiCr₂O₄ and C₁52Cr₃N_{0.48}.

20. The laser color marking method as claimed in claim 11, the laser light is a picosecond laser light or a nanosecond laser light.
